(19) United States
(12) Patent Application Publication
(10) Pub. No.: US 2003/0235721 A1
(43) Pub. Date: Dec. 25, 2003

(54) Redundant battery connections

(75) Inventors: Douglas G. Gilliland, Santa Ana, CA (US); Donald J. Glaser, Huntington Beach, CA (US)

Correspondence Address: Fogg Slifer Polglaze Leffert & Jay, P.A., P.O. Box 581009, Minneapolis, MN, 55458-1009, US

(73) Assignee: ADC DSL Systems, Inc.

(21) Appl. No.: 10/176,770

(22) Filed: Jun. 21, 2002

(51) Int. Cl. H01M 16/00; H01M 2/26; H05K 1/18

(52) U.S. Cl. 429/9; 429/121; 361/748

(57) ABSTRACT

An electronic module having a circuit card with a power supply is provided. The electronic module has two independent battery-return paths. One of the two independent battery-return paths is connectable to a battery-return side of a primary battery, and another of the two independent battery-return paths is connectable to a battery-return side of a secondary battery that replaces the primary battery when the primary battery fails. The two independent battery-return paths are connected together at a battery-return pin of the power supply.

### TECHNICAL FIELD

The present invention relates generally to the field of electronics and, in particular, to redundant battery connections.

### BACKGROUND

In many applications, electronic modules, such as telecommunications modules, include a number of circuit cards, e.g., line cards, management cards, or the like. Many of these circuit cards have power supplies, e.g., DC-to-DC power supplies or converters, for providing voltages to electronic components of the cards, such as logic devices or the like. These power supplies are usually connected to a battery for receiving power. Frequently, redundant batteries, e.g., a primary battery and a secondary (or backup) battery are connected to the power supplies of each of the circuit cards so that when the primary battery fails the secondary battery takes over for the primary battery to power the electronic module.

In many telecommunications applications, for example, power sides of the primary and secondary batteries usually are respectively connected to separate power paths of the electronic module that are connected together at a power pin of the power supply of each of the circuit cards. Battery-returns of the primary and secondary batteries are usually connected to a common battery-return path of the electronic module that is connected to a battery-return pin of the power supply of each of the circuit cards. However, this creates a single-point of failure within the electronic module for the redundant batteries. For example, an over voltage on the power side can cause a failure at the battery-return pin of the power supply of one of the circuit cards that will disconnect the battery-return sides of both the primary and secondary batteries from the electronic module, e.g., the power supplies of the other circuit cards of the electronic module, resulting in a loss of power to the electronic module.

For the reasons stated above, and for other reasons stated below that will become apparent to those skilled in the art upon reading and understanding the present specification, there is a need in the art for eliminating single-point of failures within electronic modules for redundant batteries.

### SUMMARY

The above-mentioned problems with redundant batteries and other problems are addressed by embodiments of the present invention and will be understood by reading and studying the following specification.

One embodiment provides a circuit card having a substrate. A power supply is disposed on the substrate. A pair of traces is disposed within or on the substrate. The pair of traces is connected together at a battery-return pin of the power supply. One of the pair of traces is connectable to a battery-return side of a primary battery, and another of the pair of traces is connectable to a battery-return side of a secondary battery that replaces the primary battery when the primary battery fails.

Another embodiment provides an electronic module having a circuit card with a power supply. The electronic module has two independent battery-return paths. One of the two independent battery-return paths is connectable to a battery-return side of a primary battery, and another of the two independent battery-return paths is connectable to a battery-return side of a secondary battery that replaces the primary battery when the primary battery fails. The two independent battery-return paths are connected together at a battery-return pin of the power supply.

Another embodiment provides an electronic module having a backplane. A pair of first traces is disposed within or on the backplane. One of the pair of first traces is connectable to a battery-return side of a primary battery, and another of the pair of first traces is connectable to a battery-return side of a secondary battery that replaces the primary battery when the primary battery fails. A circuit card is electrically connected to the backplane such that each of a pair of second traces disposed within or on the circuit card is respectively connected to each of the pair of first traces disposed within or on the backplane. The pair of second traces is connected together at a battery-return pin of a power supply of the circuit card.

Other embodiments are described and claimed.

### BRIEF DESCRIPTION OF THE DRAWINGS

FIG. 1 illustrates an electronic module according to an embodiment of the present invention.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense.

Embodiments of the present invention provide for respectively connecting battery-returns of a primary battery and a secondary battery to independent battery-return paths of an electronic module. The independent battery return paths are connected together at a battery-return pin of a power supply on a circuit card of the electronic module. This eliminates a single-point of failure within the electronic module for the redundant batteries created by connecting battery-returns of primary and secondary batteries to a common battery-return path of an electronic module and connecting the common battery-return path to a battery-return pin of a power supply on a circuit card of the electronic module.

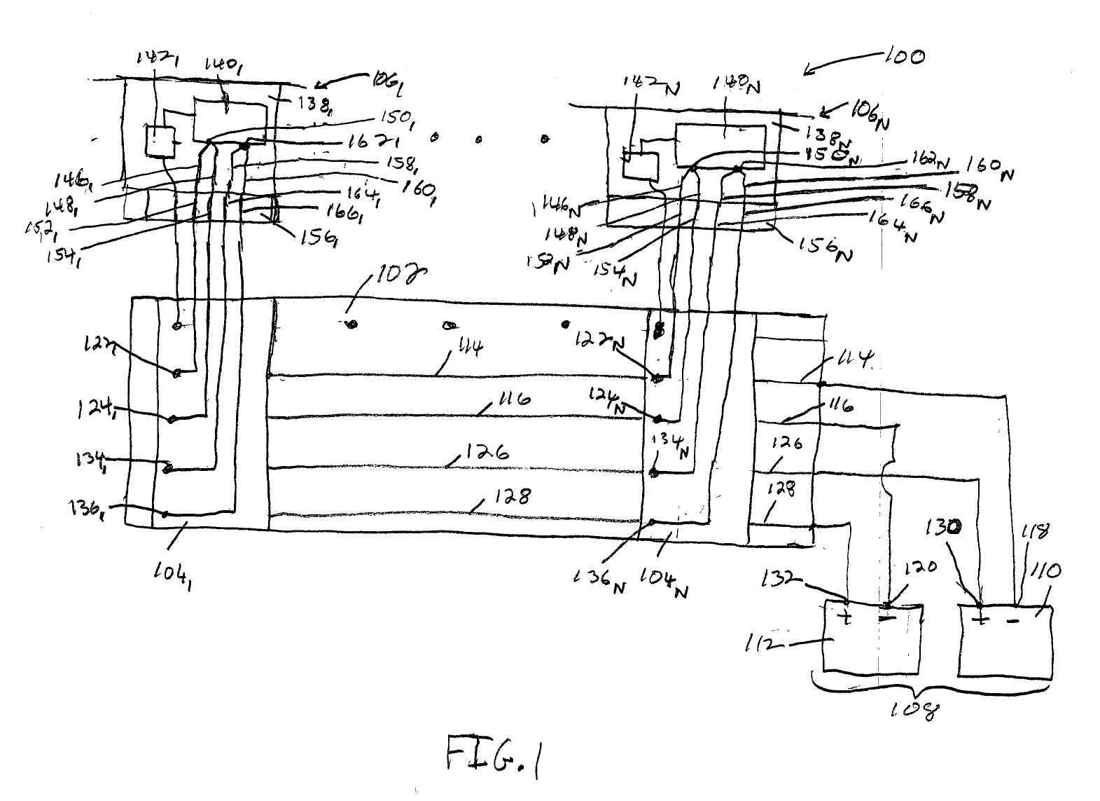

FIG. 1 illustrates an electronic module 100, such as an electronic module of a telecommunications system. Electronic module 100 includes a backplane 102 having electrical connectors 104₁ to 104_{N} electrically connected thereto. Circuit cards 106₁ to 106_{N} are respectively connected to each of connectors 104₁ to 104_{N} and thus to backplane 102. In one embodiment, circuit cards 106 are line cards, management cards, or the like of a telecommunications system. Electronic module 100 is connectable to redundant batteries 108 that include a primary battery 110 and a secondary battery 112 that replaces primary battery 110 when primary battery 110 fails, e.g., cannot provide enough power to power electronic module 100.

Traces 114 and 116 are disposed within or on backplane 102 for respectively providing separate battery-return paths for primary battery 110 and secondary battery 112. In particular, trace 114 is connectable to a battery-return side 118 of primary battery 110, and trace 116 is connectable to a battery-return side 120 of secondary battery 112. In one embodiment, traces 114 and 116 are respectively connected to battery-return pins 122 and 124 of each of connectors 104₁ to 104_{N}.

Traces 126 and 128 are disposed within or on backplane 102 for respectively providing separate power paths for primary battery 110 and secondary battery 112. In particular, trace 126 is connectable to a power side 130 of primary battery 110, and trace 128 is connectable to a power side 132 of secondary battery 112. In one embodiment, traces 126 and 128 are respectively connected to power pins 134 and 136 of each of connectors 104₁ to 104_{N}.

Each of circuit cards 106₁ to 106_{N} includes a substrate 138. A power supply 140, e.g., a DC-to-DC power supply or converter, is disposed on substrate 138. Functional circuitry 142, such as logic devices or the like, is also disposed on substrate 138 and is connected to power supply 140 for receiving power therefrom. Traces 146 and 148 are disposed within or on substrate 138 and are connected together at a battery-return pin 150 of power supply 140. In one embodiment, traces 146 and 148 are respectively connected to battery-return pins 152 and 154 of an edge connector 156 disposed on substrate 138.

The edge connector 156 of each of circuit cards 106₁ to 106_{N} respectively connects each of circuit cards 106₁ to 106_{N} to each of connectors 104₁ to 104_{N} of backplane 102. Connecting circuit cards 106 to connectors 104 respectively connects battery-return pins 152 and 154 of the edge connector 156 of each of circuit cards 106 to battery-return pins 122 and 124 of each of connectors 104. This respectively connects traces 146 and 148 of each of circuit cards 106 to traces 114 and 116 of backplane 102 so that battery-return sides 118 and 120 are connected together at the battery-return pin 150 of the power supply 140 of each of circuit cards 106.

Traces 158 and 160 are disposed within or on substrate 138 and are connected together at a power pin 162 of power supply 140. In one embodiment, traces 158 and 160 are respectively connected to power pins 164 and 166 of edge connector 156. Connecting circuit cards 106 to connectors 104 respectively connects power pins 164 and 166 of the edge connector 156 of each of circuit cards 106 to power pins 134 and 136 of each of connectors 104. This respectively connects traces 158 and 160 of each of circuit cards 106 to traces 126 and 128 of backplane 102 so that power sides 130 and 132 are connected together at power pin 162 of the power supply 140 of each of circuit cards 106.

### Conclusion

Embodiments of the present invention have been described. The embodiments provide for respectively connecting battery-returns of a primary battery and a secondary battery to independent battery-return paths of an electronic module. The independent battery return paths are connected together at a battery-return pin of a power supply on a circuit card of the electronic module. This eliminates a single-point of failure within the electronic module for the redundant batteries created by connecting battery-returns of primary and secondary batteries to a common battery-return path of an electronic module and connecting the common battery-return path to a battery-return pin of a power supply on a circuit card of the electronic module.

Although specific embodiments have been illustrated and described in this specification, it will be appreciated by those of ordinary skill in the art that any arrangement that is calculated to achieve the same purpose may be substituted for the specific embodiment shown. This application is intended to cover any adaptations or variations of the present invention. For example, the term “pin” should not be limited to a specific physical design, but is intended to represent any electrical interconnection. In addition, the power sides of primary battery 110 and secondary battery 112 are not limited to positive polarities, and the battery-return sides of primary battery 110 and secondary battery 112 are not limited to negative polarities, as shown. Instead, the power sides of primary battery 110 and secondary battery 112 can have negative polarities, and the battery-return sides of primary battery 110 and secondary battery 112 can have positive polarities. It is manifestly intended that this invention be limited only by the following claims and equivalents thereof.

What is claimed is:

1. A circuit card comprising:
a substrate;
a power supply disposed on the substrate; and
a pair of first traces disposed within or on the substrate, the pair of first traces connected together at a battery-return pin of the power supply, wherein one of the pair of first traces is connectable to a battery-return side of a primary battery and another of the pair of first traces is connectable to a battery-return side of a secondary battery that replaces the primary battery when the primary battery fails.

2. The circuit card of claim 1, further comprising a pair of second traces disposed within or on the substrate connected to a power pin of the circuit card, wherein one of the pair of second traces is connectable to a power side of the primary battery and another of the pair of second traces is connectable to a power side of the secondary battery.

3. The circuit card of claim 1, further comprising functional circuitry disposed on the substrate and connected to the power supply.

4. The circuit card of claim 1, further comprising an edge connector disposed on the substrate having a pair of battery-return pins respectively connected to the pair of first traces.

5. The circuit card of claim 1, wherein the circuit card is connectable to a backplane adapted to respectively connect each of the pair of first traces to the battery-return side of each of the primary and secondary batteries.

6. The circuit card of claim 1, wherein each of the pair of first traces is connectable to each of a pair of independent battery-return paths of an electronic module, wherein each of the pair of independent battery-return paths are respectively connectable to the battery-return side of the primary battery and to the battery-return side of the secondary battery.

7. An electronic module comprising:
a circuit card having a power supply; and
two independent battery-return paths, one of the two independent battery-return paths connectable to a battery-return side of a primary battery and another of the two independent battery-return paths connectable to a battery-return side of a secondary battery that replaces the primary battery when the primary battery fails, the two independent battery-return paths connected together at a battery-return pin of the power supply.

8. The electronic module of claim 7, further comprising two independent power paths, one of the two independent power paths connectable to a power side of a primary battery and another of the two independent power paths connectable to a power side of the secondary battery, the two independent power paths connected together at a power pin of the power supply.

9. The electronic module of claim 7, wherein each of the two independent battery-return paths comprises a trace disposed within or on a backplane of the electronic module and a trace disposed within or on the circuit card that is connected to the trace disposed within or on the backplane.

10. The electronic module of claim 7, wherein the circuit card comprises a plurality of circuit cards.

11. An electronic module comprising:
a backplane;
a pair of first traces disposed within or on the backplane, wherein one of the pair of first traces is connectable to a battery-return side of a primary battery and another of the pair of first traces is connectable to a battery-return side of a secondary battery that replaces the primary battery when the primary battery fails; and
a circuit card electrically connected to the backplane such that each of a pair of second traces disposed within or on the circuit card is respectively connected to each of the pair of first traces disposed within or on the backplane, wherein the pair of second traces is connected together at a battery-return pin of a power supply of the circuit card.

12. The electronic module of claim 11, further comprising a pair of third traces disposed within or on the backplane, wherein one of the pair of third traces is connectable to a power side of the primary battery and another of the pair of third traces is connectable to a power side of the secondary battery, wherein the pair of third traces is connected together at a power pin of the power supply.

13. The electronic module of claim 11, wherein an electrical connector disposed on the backplane electrically connects the circuit card to the backplane.

14. The electronic module of claim 11, wherein the circuit card comprises a plurality of circuit cards.

15. A method for manufacturing a circuit card, the method comprising:
disposing a power supply on a substrate;
disposing a pair of first traces on the substrate, wherein one of the pair of first traces is connectable to a battery-return side of a primary battery and another of the pair of first traces is connectable to a battery-return side of a secondary battery that replaces the primary battery when the primary battery fails; and
connecting the pair of first traces together at a battery-return pin of the power supply.

16. The method of claim 15, further comprising disposing a pair of second traces on the substrate, wherein one of the pair of second traces is connectable to a power side of the primary battery and another of the pair of second traces is connectable to a power side of the secondary battery.

17. The method of claim 16, further comprising connecting the pair of second traces to a power pin of the power supply.

18. The method of claim 15, further comprising disposing an edge connector on the substrate.

19. The method of claim 15, further comprising respectively connecting the pair of first traces to a pair of battery-return pins of an edge connector disposed on the substrate.

20. The method of claim 15, further comprising disposing functional circuitry on the substrate.

21. The method of claim 15, further comprising connecting the power supply to functional circuitry disposed on the substrate.

22. A method for connecting redundant batteries to a circuit card, the method comprising:
connecting a pair of first traces disposed within or on the circuit card to a battery-return pin of a power supply disposed on the circuit card;
connecting a battery-return side of a primary battery to one of the pair of first traces;
connecting a battery-return side of a secondary battery that replaces the primary battery when the primary battery fails to another of the pair of first traces so that the battery-return sides of the primary and secondary batteries are connected together at the battery-return pin of the power supply; and
connecting a power side of the primary battery and a power side of the secondary battery to the power supply.

23. The method of claim 22, wherein connecting the power side of the primary battery and the power side of the secondary battery to the power supply comprises connecting a pair of second traces disposed within or on the circuit card to a power pin of the power supply and respectively connecting each of the pair of second traces to the power side of the primary battery and the power side of the secondary battery.

24. A method for connecting redundant batteries to an electronic module, the method comprising:
respectively connecting battery-return sides of a primary battery and a secondary battery to independent battery-return paths of the electronic module;
connecting the independent battery-return paths together at a battery-return pin of a power supply of a circuit card of the electronic module; and
connecting power sides of the primary battery and the secondary battery to the power supply.

25. The method of claim 24, wherein respectively connecting the battery-return sides of the primary battery and the secondary battery to the independent battery-return paths of the electronic module comprises respectively connecting the battery-return sides to independent traces of a backplane of the electronic module.

26. The method of claim 24, wherein connecting the independent battery-return paths together at the battery-return pin of the power supply comprises respectively connecting the independent battery-return paths to a pair of traces of the circuit card and connecting the pair of traces together at the battery-return pin.

27. The method of claim 24, wherein connecting the power sides of the primary battery and the secondary battery to the power supply comprises respectively connecting the power sides to independent power paths of the electronic module.

28. The method of claim 27, wherein connecting the power sides of the primary battery and the secondary battery to the power supply further comprises connecting the independent power paths together at a power pin of the power supply.

29. A method for connecting redundant batteries to an electronic module, the method comprising:
connecting a pair of first traces disposed within or on a circuit card of the electronic module together at a battery-return pin of a power supply disposed on the circuit card;
respectively connecting each of the pair of first traces to each of a pair of second traces disposed within or on a backplane of the electronic module;
connecting a battery-return side of a primary battery to one of the pair of second traces;
connecting a battery-return side of a secondary battery that replaces the primary battery when the primary battery fails to another of the pair of second traces so that the battery-return sides of the primary and secondary batteries are connected together at the battery-return pin of the power supply; and
connecting power sides of the primary battery and the secondary battery to the power supply.

30. The method of claim 29, wherein connecting the power sides of the primary battery and the secondary battery to the power supply comprises respectively connecting the power sides to a pair of third traces disposed within or on the backplane.

31. The method of claim 30, wherein connecting the power sides of the primary battery and the secondary battery to the power supply further comprises respectively connecting each of the pair of third traces to each of a pair of fourth traces disposed within or on the circuit card and connecting the pair of fourth traces together at a power pin of the power supply.
